(19) United States
(12) Patent Application Publication
(10) Pub. No.: US 2004/0110351 A1
(43) Pub. Date: Jun. 10, 2004

(54) Method and structure for reduction of junction capacitance in a semiconductor device and formation of a uniformly lowered threshold voltage device

(75) Inventor: Shreesh Narasimha, Beacon, NY (US)

Correspondence Address: Sean F. Sullivan, Esq., Cantor Colburn LLP, 55 Griffin Road South, Bloomfield, CT, 06002, US

(73) Assignee: INTERNATIONAL BUSINESS MACHINES CORPORATION, ARMONK, NY (US)

(21) Appl. No.: 10/314,023

(22) Filed: Dec. 5, 2002

(51) Int. Cl. H01L 21/336; H01L 21/425

(52) U.S. Cl. 438/302; 438/305; 438/307; 438/525

(57) ABSTRACT

A method of manufacturing a semiconductor device comprises implanting at an angle of about 20 to about 70 degrees a first halo dose of a dopant about a first portion of a perimeter of a source extension implant or a drain extension implant, wherein the first portion comprises a near channel region; and implanting at an angle of about 0 to about 20 degrees a second halo dose of the dopant about a second portion of the perimeter of the source extension implant or the drain extension implant, wherein the second portion is substantially free of the first portion, and wherein the angles are measured with respect to a vertical axis through the semiconductor device.

### BACKGROUND

The present disclosure relates generally to the manufacture of integrated circuit devices and, more particularly, to a method and structure for reducing junction capacitance.

In the manufacture of semiconductor devices such as metal oxide semiconductors field effect transistors (MOSFETs), advances in process technology and digital system architecture have led to integrated circuits having increased operating frequencies. These increased operating frequencies have been accompanied by faster and smaller integrated circuits.

One way to improve integrated circuit switching speed is by reducing the loading capacitance of MOSFETs. Transistor loading capacitance generally has three components: intrinsic gate capacitance, overlap capacitance, and junction capacitance. Junction capacitance occurs as a result of the capacitive coupling between the source and drain terminals of a semiconductor device with the substrate, by virtue of the junction therebetween. Junction capacitance generally promotes an increase in the amount of time taken by a semiconductor device to charge and discharge, thereby resulting in slower performing devices. It is therefore desirable to find methods and structures for semiconductor devices by which junction capacitance may be reduced.

Another way to improve speed in a complex integrated circuit such as, for example, a complimentary metal oxide semiconductor (CMOS) is to replace the standard threshold voltage (Vₜ) devices in slow paths with lower Vₜ devices. For this reason, high performance CMOS technologies usually include a low Vₜ device offering in their standard package. It is generally desirable to maintain a uniform difference in the threshold voltage between a low threshold voltage semiconductor device and a standard threshold voltage semiconductor device across a the gatelength range. If the difference in threshold voltage is too small, then the ability to speed up slow paths in circuits is diminished. On the other hand, if the difference is too high, then the sub-threshold leakage will be excessive, creating high levels of static power dissipation. It is therefore desirable to provide a method whereby the junction capacitance is lowered in a short channel MOSFET for a given threshold voltage level, or the Vₜ is uniformly lowered in the short gatelength regime while simultaneously lowering junction capacitance.

### SUMMARY

In one embodiment, a method of manufacturing a semiconductor device includes implanting at an angle of about 20 to about 70 degrees a first halo dose of a dopant about a first portion of a perimeter of a source extension implant or a drain extension implant, wherein the first portion comprises a near channel region; and implanting at an angle of about 0 to about 20 degrees a second halo dose of the dopant about a second portion of the perimeter of the source extension implant or the drain extension implant, wherein the second portion is substantially free of the first portion, wherein the angles are measured with respect to a vertical axis through the semiconductor device.

In another embodiment, a semiconductor device includes a halo implant about a periphery of a source and drain extension region. The halo implant includes a first dopant concentration in a near channel region, and a second dopant concentration about a perimeter of the source extension implant or drain extension implant free of the near channel region.

The above described and other features are exemplified by the following figures and detailed description.

### BRIEF DESCRIPTION OF THE DRAWINGS

Referring now to the Figures, which represents an exemplary embodiment of a semiconductor device, wherein like elements are numbered alike:

FIG. 1 is a graphical representation of the uniform lowering of channel threshold voltage across the gate length with a simultaneous lowering of junction capacitance as may be achieved by the use of a second halo dose of dopant in the source and drain extension regions;

FIG. 2 is a graphical representation of the non-uniform lowering of threshold voltage across the gate length as is generally achieved by the use the well implant method;

FIG. 3 is a cross sectional view of one embodiment of a transistor;

FIG. 4 is an enlarged partial cross sectional view corresponding to FIG. 3 illustrating a first halo dose; and

FIG. 5 is an enlarged partial cross sectional view corresponding to FIG. 3 illustrating a second halo dose.

### DETAILED DESCRIPTION OF PREFERRED EMBODIMENTS

Disclosed herein is a process and a structure for reducing junction capacitance in a semiconductor device. Additionally disclosed herein is a process and a structure for reducing the junction capacitance (Cⱼ) while simultaneously reducing the threshold voltage (Vₜ) uniformly across a gate length span. The process generally comprises implanting a first halo dose of a first dopant about a perimeter of a source and drain implant extension (hereinafter S/D extension) in a near channel region and implanting a second halo dose of a dopant about a perimeter of the rest of the S/D extensions, wherein the first halo dose is implanted at an angle of about 20 degrees to about 70 degrees and the second halo dose is implanted at an angle of less than or equal to about 20 degrees axial to the substrate, and wherein the first halo dose is higher than the second halo dose. By virtue of the angle difference between the first halo dose of dopant and the second halo dose of dopant, the CJ can be reduced without any change in the threshold voltage of the short channel field effect transistor (FET). By altering the implant energy, angle, and dosage of the second halo dose of dopant, the short channel threshold voltage can be lowered uniformly across a gatelength regime with a simultaneous reduction in Cⱼ. Additionally, by reducing the threshold voltage, slow paths in complex circuits can be speeded up thus enabling the development of low Vₜ devices. This preservation of short channel control, minimization of junction capacitance and the uniform reduction in threshold voltage is especially advantageous in semiconductor devices having gate stack dimensions of less than or equal to about 0.13 micrometers. As defined herein, the terms ‘first’ and ‘second’ are not intended to imply a sequence or order for the halo doses.

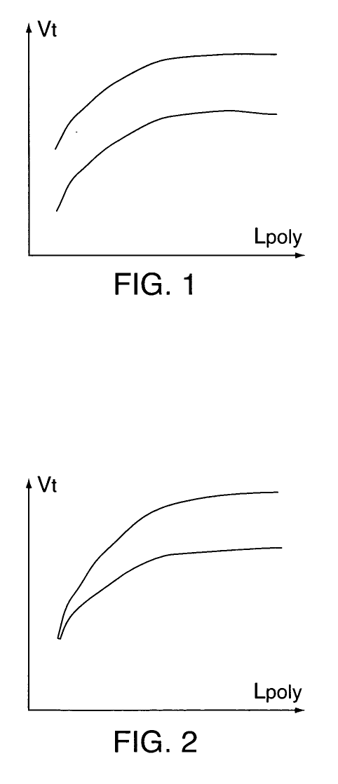

FIGS. 1 and 2 are graphical representations of the reduction in threshold voltage achieved by the halo implant method and the well implant method respectively. As can be seen from FIG. 1, the implantation of the second halo dose of dopant at an angle of less than or equal to about 20 degrees results in a uniform reduction in the threshold voltage across the gate length. This is generally accomplished by adjusting the dosage and the angle of the second halo dose of dopant so as to obtain a reduction of the Vₜ across the gatelength span. This results in a low Vₜ device offering that can be used to improve circuit speed in a complex CMOS circuit. In contrast, FIG. 2 reflects the result of utilizing well implants to reduce the threshold voltage. The use of well implants does not reduce the threshold voltage uniformly across the gate span as is achieved by the implantation of the second halo dose of dopant in the S/D extension regions.

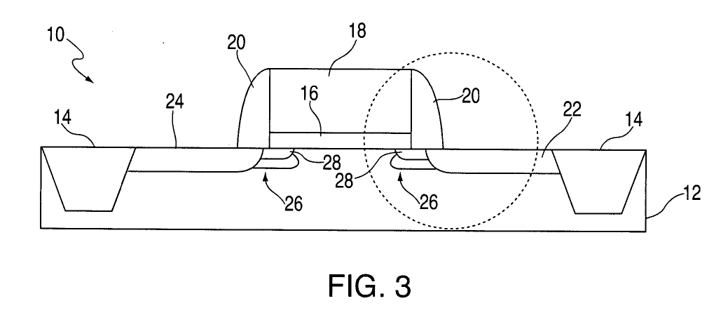

FIG. 3 illustrates an exemplary semiconductor device structure generally designated 10. As shown, the semiconductor device structure 10 generally includes a substrate 12 upon which the device 10 is fabricated. The substrate 12 may be a silicon wafer, a silicon on insulator (SOD substrate, or the like. Isolation trenches 14 are provided to electrically isolate adjacent active area regions. The active areas generally include a gate stack comprising a gate oxide layer 16 and a polysilicon layer 18. A sidewall spacer 20 is generally applied to the sidewalls of the gate stack. The isolation trenches 14 are typically filled with a dielectric material, e.g., an oxide, followed by an etch back step in order to planarize the surface of the substrate 12. The semiconductor device structure 10 further includes source regions 22 and drain regions 24 resulting from deep implants as well as extension implants 26, 28 to improve short channel and series resistance to control short channel and series resistance effects. The source/drain extension regions 22, 24 further include a halo implant 26 about a periphery of the extension regions. As will be appreciated by those skilled in the art, the semiconductor device structure 10 may further include additional structures including, but not limited to, p-well implants, n-well implants, silicides, intermetal oxides, and the like.

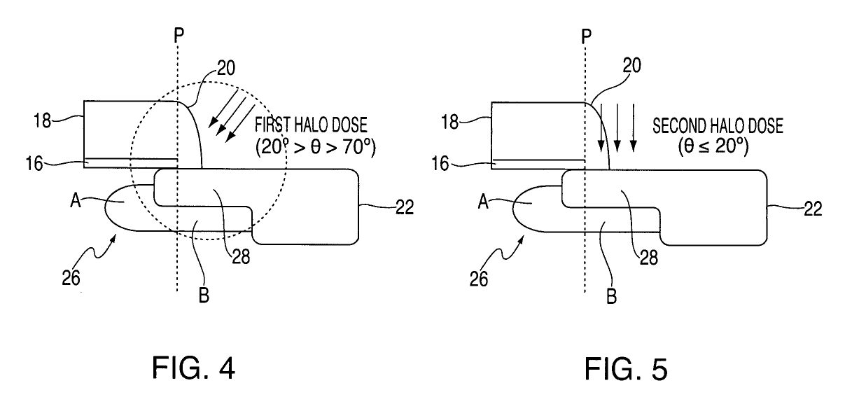

As shown more clearly in FIGS. 4 and 5, the halo implant 26 preferably comprises a first halo dose of a dopant about a first portion A of a perimeter of the source and drain extensions 22, 24, wherein the first portion A comprises a near channel region. As used herein, the term “near channel region” refers to an area abutting the perimeter of the source or drain extension 22 or 24 and underlying the gate stack, i.e., as defined in FIGS. 4 and 5 by a vertical axis P coaxial with a sidewall of the gate stack. The angle of delivery (θ) of the first halo dose of dopant is preferably in an amount of about 20 degrees to about 70 degrees measured from a vertical axis P as shown in FIG. 4. Within this range it is generally desirable to use an angle of delivery of greater than or equal to about 22 degrees, preferably greater than or equal to about 25 degrees. Also desirable within this range is an angle of less than or equal to about 60 degrees, preferably less than or equal to about 55 degrees measured as indicated above. The preferred angle is 30 degrees.

The halo implant region 26 further includes a second halo dose of the dopant about a second portion B of the perimeter of source and drain extension 22, 24, wherein the second portion preferably does not overlap with the first portion. The second halo dose, i.e., a compensating dose, which is designed to minimize the junction capacitance at the extension perimeter of the S/D extension implants 26, 28 is preferably delivered at an angle θ of less than or equal to about 20 degrees relative to vertical axis P. Within this range, an angle of greater than or equal to about 1, preferably greater than or equal to about 2 degrees is desirable. Also desirable, within this range is a delivery angle of less than or equal to about 18 degrees, preferably less than or equal to about 15 degrees.

Depending on the particular desired circuitry, the semiconductor device may be defined as either a P channel field effect transistor (PFET device) or as an N channel field effect transistor (NFET device). In the case of PFET devices the preferred ion dopant for implantation is boron in the S/D extension region 22, 24 which is generally derived from compounds such boron trifluoride (BF₃), boron tribromide (BBr₃), boron trioxide (B₂O₃), dirborane (B₂H₆), boron trichloride (BCl₃), boron nitride (BN), indium, gallium and combinations comprising at least one of the foregoing. For ion implantation, the dopants are generally in the form of a gas or a solid. Gases are generally preferred for ion implantation because of their ease of use and higher control. The first halo dose of dopant is a dopant selected from the group consisting of arsenic, antimony, phosphorus, and combinations comprising at least one of the foregoing is applied to the near channel region, while in order to reduce the junction capacitance in a PFET device, the second halo dose of dopant selected from the group consisting of boron, indium, gallium, and combinations comprising at least one of the foregoing is applied to the perimeter of the source or drain extension region. The second halo dose can be used to either lower Cⱼ without any change in short channel Vₜ or lower short channel Vₜ across gatelength while simultaneously lowering Cⱼ. It is generally known that the junction depth and the overlap of the S/D extension implants with the gate stack play a role in the scaling or size of the semiconductor device 10. As defined herein, and as can be seen in FIGS. 4 and 5, the depth is referred to as the junction depth of the S/D extension implants 26, 28 and is measured as the distance from the lower surface of the oxide layer to the bottom of the S/D extension implant 26, 28. The overlap region is defined as the distance the S/D extension implant 26, 28, extends under the gate stack from the vertical axis P seen in FIGS. 4 and 5.

For PFET devices, the first halo dose is a dopant selected from the group consisting of antimony, arsenic, phosphorus, and combinations comprising at least one of the foregoing and preferably comprises a dosage of about 3 e¹³ atoms/cm² to about 10.5 e¹⁴ atoms/cm². More preferably, the dosage for the first halo dose of dopant is about 5 e¹³ atoms/cm² to about 7 e¹³ atoms/cm². The dopant implanted in this manner is preferably implanted up to a depth of 150 angstroms (A) to about 700 Å with an overlap of about 0 Å to about 300 Å under the gate stack. The second halo dose of dopant for a PFET device is selected from the group consisting of boron, gallium, indium, and combinations comprising at least one of the foregoing and preferably comprises a dosage of about 5 e¹² atoms/cm² to about 1 e¹⁴ atoms/cm². More preferably, the dosage for the second halo dose of dopant comprises a dosage of about 2 e¹³ atoms/cm² to about 3 e¹³ atoms/cm². The dopant may be implanted up to a depth of about 150 Å to about 700 Å.

In NFET devices, the dopant ions implanted in the S/D extension regions 22, 24, include, among others, antimony, arsenic, phosphorus, and combinations comprising at least one of the foregoing dopant ions. Antimony is generally obtained from antimony trioxide (Sb₂O₃), while arsenic is derived from compounds such as arsenic trioxide (As₂O₃) or arsine (AsH₃). Phosphorus is generally derived from phosphorus oxychloride (POCl₃), phosphorus pentoxide (P₂O₅) and phosphine (PH₃). The preferred dopant for the S/D extension region of an NFET device is arsenic. In an NFET device, a first halo dose of dopant selected from the group consisting of boron, indium, gallium, and combinations comprising at least one of the foregoing dopants is implanted in the near channel region of the semiconductor device. In order to reduce the junction capacitance, as well as to reduce the Vₜ across the gate length, a second halo dose of dopant selected from the group consisting of antimony, arsenic, phosphorus, and combinations comprising at least one of the foregoing dopants is applied to the perimeter of the source or drain extension region 22, 24.

For NFET devices, the first halo dose is selected from the group consisting of boron, indium, gallium, and combinations comprising at least one of the foregoing dopants and preferably comprises a dosage of about 3 e¹³ atoms/cm² to about 2.5 e¹⁴ atoms/cm². More preferably, the dosage for the first halo dose of dopant is about 8 e¹³ atoms/cm² to about 10.5 e¹⁴ atoms/cm². The dopant implanted in this manner is preferably implanted up to a depth of about 150 Å to about 700 Å with an overlap of about 0 Å to about 300 Å under the gate stack. The second halo dose of dopant is selected from the group consisting of arsenic, antimony, phosphorus, and combinations comprising at least one of the foregoing dopants and preferably comprises a dosage of about 5 e¹² atoms/cm² to about 1.5 e¹⁴ atoms/cm². More preferably, the dosage for the second halo dose of dopant is at about 2 e¹³ atoms/cm² to about 3 e¹³ atoms/cm². Preferably, the dopant is implanted up to a depth of 150 Å to about 700 Å.

Following implantation of the dopant ions, the semiconductor device may be annealed at temperatures of about 900 to about 1,050° C. The thermal annealing facilitates the activation and diffusion of the dopant ions and also helps repair defects in the silicon film.

The first halo dose of dopant may be implanted simultaneously or sequentially with the second halo dose of dopant. It is generally preferred to implant the respective halo doses of dopant in sequential fashion i.e., the first halo dose of dopant followed the second halo dose of the dopant, and vice versa.

In summary, the advantageous addition of a first halo dose of dopant to the near channel regions of the source and drain extension implants 26, 28, provides good short channel threshold voltage Vₜ control, while the advantageous use of a second halo dose of dopant permits minimization of the junction capacitance. The second halo dose of dopant lowers the effective halo doping along much of the source and drain extension 22, 24, perimeter, which in turn lowers the perimeter junction capacitance. It may be used in silicon wafers as well as on SOI substrates. In general the junction capacitance may be reduced by 20% to about 50% over a semiconductor device wherein a second halo dose of dopant is not implanted at the extension perimeter of the S/D extension implant. This method of reduction of junction capacitance can be utilized in metal oxide semiconductors, complimentary metal oxide semiconductors or silicon on insulator complimentary metal oxide semiconductors. The technology can be advantageously used in semiconductor devices having a gate dimensions of less than or equal to about 0.25 micrometers, preferably less than or equal to about 0.20 micrometers, more preferably less than or equal to about 0.13 micrometers and most preferably less than or equal to about 0.10 micrometers.

Additionally, the second halo dose of dopant can be modified to result in a uniform reduction of the Vₜ across a large gatelength span. This results in a low Vₜ device offering that can be used to improve circuit speed in a complex CMOS circuit. This reduction in the Vₜ is accomplished simultaneously with the reduction in junction capacitance and the reduction in the Vₜ is preferably from about 1 millivolt (mV) to about 200 mV. Within this range it is desirable to have a reduction of greater than or equal to about 50 mV, preferably about 90 mV. Also desirable within this range is a reduction in Vₜ of less than or equal to about 150 mV, preferably less than or equal to about 100 mV. This method of reduction of threshold voltage with the accompanying reduction in junction capacitance can also be utilized in metal oxide semiconductors, complimentary metal oxide semiconductors or silicon on insulator complimentary metal oxide semiconductors.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of manufacturing a semiconductor device comprising:
implanting at an angle of about 20 to about 70 degrees a first halo dose of a dopant about a first portion of a perimeter of a source extension implant or a drain extension implant, wherein the first portion comprises a near channel region; and
implanting at an angle of about 0 to about 20 degrees a second halo dose of a dopant about a second portion of the perimeter of the source extension implant or the drain extension implant, wherein the second portion is substantially free of the first portion, and wherein the angles are measured with respect to a vertical axis through the semiconductor device.

2. The method of claim 1, wherein the semiconductor device comprises a P channel field effect transistor, wherein the dopant of the first halo dose is selected from the group consisting of antimony, arsenic, phosphorus, and combinations comprising at least one of the foregoing dopants, and wherein the dopant of the second halo dose is selected from the group consisting of boron, indium, gallium, and combinations comprising at least one of the foregoing dopants.

3. The method of claim 2, wherein implanting the first halo dose comprises a dosage of the dopant at about 3 e¹³ atoms/cm² to about 1.5 e¹⁴ atoms/cm².

4. The method of claim 2, wherein implanting the second halo dose comprises a dosage of the dopant at about 5 e¹² atoms/cm² to about 1 e¹⁴ atoms/cm².

5. The method of claim 1, wherein the semiconductor device comprises an N channel field effect transistor, wherein the dopant of the first halo dose is selected from the group consisting of boron, indium, gallium, and combinations comprising at least one of the foregoing dopants, and wherein the dopant of the second halo dose is selected from the group consisting of antimony, arsenic, phosphorus, and combinations comprising at least one of the foregoing dopants.

6. The method of claim 5, wherein implanting the first halo dose comprises a dosage of the dopant at about 3 e¹³ atoms/cm² to about 2.5 e¹⁴ atoms/cm².

7. The method of claim 5, wherein implanting the second halo dose comprises a dosage of the dopant at about 5 e¹² atoms/cm² to about 1.5 e¹⁴ atoms/cm².

8. The method of claim 1, wherein the first halo dose is implanted at an angle of about 30 degrees to about 55 degrees.

9. The method of claim 1, wherein the second halo dose is implanted at an angle equal to or less than about 10 degrees.

10. The method of claim 1, wherein implanting the first halo dose and the second halo dose may be simultaneous or sequential.

11. A semiconductor device comprising:
a halo implant about a periphery of a source and drain extension region, wherein the halo implant comprises a first dopant in a near channel region, and a second dopant about a perimeter of the source extension implant or drain extension implant free of the near channel region.

12. The semiconductor device of claim 11, wherein the first dopant is selected from the group consisting of arsenic, antimony and phosphorus, and wherein the second dopant is selected from the group consisting of boron, gallium and indium.

13. The semiconductor device of claim 12, wherein the concentration of the first dopant is at about 3 e¹³ atoms/cm² to about 1.5 e¹⁴ atoms/cm², and wherein the concentration of the second dopant is at about 5 e¹² atoms/cm² to about 5 e¹³ atoms/cm².

14. The semiconductor device of claim 11, wherein the first dopant is selected from the group consisting of boron, gallium and indium, and wherein the second dopant is selected from the group consisting of arsenic, antimony, and phosphorus.

15. The semiconductor device of claim 14, wherein the concentration of the first dopant is at about is at about 3 e¹³ atoms/cm² to about 2.5 e¹⁴, and wherein the concentration of the second dopant is at about 5 e¹² atoms/cm² to about 5 e¹³ atoms/cm².
